(19) United States
(12) Patent Application Publication
(10) Pub. No.: US 2025/0226259 A1
(43) Pub. Date: Jul. 10, 2025

(54) SUBSTRATE PROCESSING APPARATUS

(71) Applicant: SAMSUNG ELECTRONICS CO., LTD., Suwon-si (KR)

(72) Inventors: Woojin Jang, Suwon-si (KR); Kyung-Sun Kim, Suwon-si (KR); Nam Kyun Kim, Suwon-si (KR); MinGil Kim, Suwon-si (KR); Jihwan Kim, Suwon-si (KR); Donghyeon Na, Suwon-si (KR); Junghyun Song, Suwon-si (KR); Kuihyun Yoon, Suwon-si (KR); Dongseok Han, Suwon-si (KR)

(21) Appl. No.: 19/006,779

(22) Filed: Dec. 31, 2024

(30) Foreign Application Priority Data
Jan. 4, 2024 (KR) 10-2024-0001438

(51) Int. Cl. H01L 21/687; H01J 37/32

(52) U.S. Cl. CPC H01L 21/68785; H01J 37/32715; H01J 37/32834; H01J 2237/0041

(57) ABSTRACT

An example support assembly used in a substrate processing apparatus that process a substrate by using plasma includes a base member, a support plate disposed on the base member, an insulation member disposed on at least a partial region of an outer circumference of the base member, and a discharge passage located in the insulation member. The discharge passage has an outer end connected to an outer surface of the insulation member.

### CROSS-REFERENCE TO RELATED APPLICATION

This application claims priority to and the benefit of Korean Patent Application No. 10-2024-0001438 filed in the Korean Intellectual Property Office on Jan. 4, 2024, the entire contents of which is incorporated herein by reference.

### BACKGROUND

To manufacture semiconductor devices, various processes such as photolithography, etching, ashing, ion implantation, thin film deposition, and cleaning are performed on the substrate to form a desired pattern on the substrate. Among these, the etching process is a process of removing a selected heating region among the films formed on the substrate, in which wet etching and dry etching are used.

Among these, an etching device using plasma may be used for dry etching. In generally, in order to form plasma, an electromagnetic field is formed in an internal space of a chamber, and the electromagnetic field excites the process gas provided in the chamber into a plasma state.

Plasma refers to an ionized gas state composed of ions, electrons, radicals, etc. Plasma is generated by very high temperatures, strong electric fields, or RF electromagnetic fields. The semiconductor device manufacturing process uses plasma to perform an etching process. The etching process may be performed by ion particles contained in plasma colliding with the substrate.

### SUMMARY

The present disclosure relates to a substrate processing apparatus capable of preventing generation of arcs therein.

However, the objective of the present disclosure is not limited to the aforementioned one, and may be extended in various ways within the spirit and scope of the present disclosure.

In general, according to some aspects, a support assembly used in a substrate processing apparatus that process a substrate by using plasma may include a base member, a support plate disposed on the base member, an insulation member disposed on at least a partial region of an outer circumference of the base member, and a discharge passage located in an interior of the insulation member, and having an outer end connected to an outer surface of the insulation member.

In general, according to some aspects, a substrate processing apparatus may include a chamber, and a support assembly disposed in an interior of the chamber, where the support assembly is provided as an assembly of a plurality of components, such that a gap is formed between the components in an interior of the support assembly and a discharge passage is located to pass through the gap, and where an outer end of the discharge passage is connected to an outer surface of the support assembly.

In general, according to some aspects, a substrate processing apparatus may include a chamber having a lower region where a discharge hole is located, a support assembly disposed in an interior of the chamber, and a baffle disposed on an outer circumference of the support assembly, where the support assembly may include a base member, a support plate disposed on the base member, an insulation member disposed on at least a partial region of an outer circumference of the base member, and a discharge passage located in an interior of the insulation member, where an outer end of the discharge passage is connected to an outer surface of the insulation member, and the outer end of the discharge passage is located below the baffle.

### BRIEF DESCRIPTION OF THE DRAWINGS

FIG. 1 is a drawing showing an example of a substrate processing apparatus.

FIG. 2 is a drawing showing an example of a partial region of the support assembly of FIG. 1.

FIG. 3 is a horizontal cross-sectional view of an example of a base member.

FIG. 4 is a drawing showing an example of the guide member of FIG. 2.

FIG. 5 is a drawing showing an example of a region adjacent to a base member and an insulation member.

FIG. 6 is a drawing showing an example of the arc prevention member of FIG. 5.

FIG. 7 is a drawing for explaining an example of a state in which discharge is made into an interior of a support assembly through a discharge passage when the substrate processing apparatus operates.

FIG. 8 is a drawing for explaining an example of a region where discharge is made into a space formed in an interior of a support assembly through a discharge passage.

FIG. 9 is a drawing showing an example of an arrangement state of an arc prevention member.

FIG. 10 is a drawing showing an example of an arc prevention member.

FIG. 11 is a drawing showing an example of a partial region of a support assembly.

FIG. 12 is a drawing showing an example of a partial region of a support assembly.

FIG. 13 is a drawing showing an example of a partial region of a support assembly.

FIG. 14 is a drawing showing an example of a partial region of a support assembly.

FIG. 15 is a drawing showing an example of a partial region of a support assembly.

FIG. 16 is a drawing showing an example of a substrate processing apparatus.

### DETAILED DESCRIPTION

The present disclosure will be described more fully hereinafter with reference to the accompanying drawings, in which implementations of the disclosure are shown. As those skilled in the art would realize, the described implementations may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

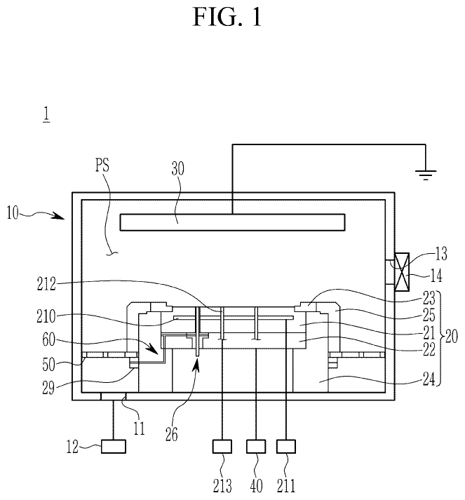

FIG. 1 is a drawing showing an example of a substrate processing apparatus 1.

Referring to FIG. 1, the substrate processing apparatus 1 may include a chamber 10, a support assembly 20 and a plasma excitation member 30.

The substrate processing apparatus 1 processes the substrate by using plasma. For example, the substrate processing apparatus 1 may perform etching process or the like by using excited plasma. The substrate may be a wafer or the like for manufacture a semiconductor device.

The chamber 10 provides a process space PS in which a substrate processing process is performed. The chamber 10 has a process space PS in an interior, and is provided in a closed and sealed shape. The chamber 10 may be made of a metal material. As an example, the chamber 10 may be made of an aluminum material. The chamber 10 may be grounded. A discharge hole 11 may be formed in one side of the chamber 10. The discharge hole 11 may be formed in a lower region of the chamber 10. Reaction by-products generated during the process and gases remaining in an interior space of the chamber 10, or the like may be discharged to the outside through the discharge hole 11. By the discharge process, the interior of the chamber 10 may be depressurized to a predetermined pressure. A discharge member 12 be may connected to the discharge hole 11. The discharge member 12 is configured to apply a negative pressure for the discharge to the interior of the chamber 10. The discharge member 12 may include at least one pump. For example, the discharge member 12 may include a turbo molecular pump.

An opening 13 may be formed on one side of the chamber 10. The opening 13 is provided as a path through which the substrate is carried in or taken out. The opening 13 may be opened or closed by a door 14.

The support assembly 20 may be disposed in the interior of the chamber 10. The support assembly 20 may be disposed in a lower portion of the process space PS. The support assembly 20 supports the substrate. The support assembly 20 may fix the substrate by using an electrostatic force. The support assembly 20 may be provided as an assembly of a plurality of components. Accordingly, in an interior of the support assembly 20, a gap may be formed between components.

The support assembly 20 may include a support plate 21, a base member 22, a focus ring 23, an insulation member 24 and an outer ring 25.

The support plate 21 may be disposed in an upper region of the support assembly 20. The support plate 21 may be provided in a plate structure having a preset thickness. An outer side circumference of the support plate 21 may be circular. An outer surface of the support plate 21 may be made of a dielectric substance. The substrate may be placed on an upper surface of the support plate 21. The area of the upper surface of the support plate 21 may correspond to the area of the substrate.

An internal electrode 210 may be disposed in an interior of the support plate 21. The internal electrode 210 may be provided in a shape corresponding to the upper surface of the support plate 21. The internal electrode 210 may be electrically connected to a fixing power supply 211. The fixing power supply 211 may include a DC power source. An electrostatic force may be generated between the internal electrode 210 and the substrate by a voltage applied by the fixing power supply 211, and the electrostatic force may fix the substrate to the support plate 21.

A heat transfer medium supply passage 212 may be formed in the interior of the support plate 21. The heat transfer medium supply passage 212 may be connected to the upper surface of the support plate 21, and may provide a path through which a heat transfer gas is supplied to the upper surface of the support plate 21. The heat transfer medium supply passage 212 may be connected to a heat transfer gas storage portion 213. The heat transfer gas storage portion 213 may supply the heat transfer gas to the heat transfer medium supply passage 212. The heat transfer gas may be an inert gas. For example, the heat transfer gas may be helium (He), or the like. In a state that the substrate is fixed to the upper surface of the support plate 21, when the heat transfer gas is supplied to the upper surface of the support plate 21, the heat transfer gas may be filled in a space formed between the support plate 21 and a bottom surface of the substrate. The heat transfer gas serves as a medium to transfer the heat of the substrate to the support assembly 20.

The base member 22 may be disposed in a lower region of the support assembly 20. The support plate 21 may be disposed on an upper surface of the base member 22. For example, the support plate 21 may be attached to the upper surface of the base member 22 by an adhesive layer. An outer side surface of the base member 22 may be aligned with a lower portion of the outer side surface of the support plate 21 in a vertical direction, such that a step may not be formed between the outer side surface of the base member 22 and the lower portion of the outer side surface of the support plate 21.

A refrigerant passage may be formed in an interior of the base member 22. The refrigerant passage may provide a path through which a cooling fluid flows in the interior of the base member 22. For example, the refrigerant passage may be spirally formed. In addition, in the refrigerant passages, passages of a ring shape having different radii may be disposed at the same center. At this time, the refrigerant passage may be formed such that the passages of ring shapes may communicate with each other. The cooling fluid may circulate through the refrigerant passage, and may cool the base member 22. The base member 22 is configured to cool the support plate 21 and the substrate, while it is cooled. That is, heat of the substrate may be transferred to the base member 22 cooled through the support plate 21.

At least a partial region of the base member 22 may be made of a metal material. For example, the base member 22 may be entirely made of a metal material. The base member 22 may be made of a material such as aluminum, or the like. Accordingly, the base member 22 may function as an electrode. A source power supply 40 be may electrically connected to a metal material region of the base member 22. The source power supply 40 may be provided as a high frequency power supply configured to generate the high frequency power. The source power supply 40 may be provided as an RF power supply. In addition, the source power supply 40 may be omitted, and the metal material region of the base member 22 may be grounded.

The focus ring 23 may be disposed in an upper outer region of the support assembly 20. The focus ring 23 may be disposed in an upper portion of the outer circumference of the support plate 21. The focus ring 23 may be disposed on the support plate 21. In addition, the focus ring 23 may be disposed on an upper edge region of the base member 22. The focus ring 23 may be provided in a ring shape. A step may be formed in an upper portion of the focus ring 23 such that an outer side portion is higher than an inner side portion. An upper inner portion of the focus ring 23 may be located at a height corresponding to the upper surface of the support plate 21. The upper inner portion of the focus ring 23 may be located below an edge region of the substrate. An upper outer portion of the focus ring 23 may be located to surround the edge region of the substrate. The focus ring 23 may improve uniformity of density distribution of plasma. The focus ring 23 may be worn during use. When the wear of the focus ring 23 is increased, the performance of controlling the density distribution of plasma may deteriorate. Accordingly, the focus ring 23 may be replaced after being used for a preset period of time or a preset number of times.

The insulation member 24 may be disposed in at least a partial region of an outer circumference of the base member 22. In addition, the insulation member 24 may be disposed in at least a partial region of the outer circumference of the support plate 21. To this end, at least a partial region of the insulation member 24 may be provided in a ring structure having a predetermined height, in the upward and downward direction. Accordingly, the region surrounded by the insulation member 24 may be isolated from the interior space of the chamber 10. The insulation member 24 may be made of an insulation material.

The insulation member 24 may be disposed to surround the entire outer surface of the base member 22. To this end, a lower end of the insulation member 24 may be disposed below a lower end of the base member 22, and an upper end of the insulation member 24 may be disposed above an upper end of the base member 22. In addition, the insulation member 24 may support the base member 22. To this end, in the insulation member 24, a step supporting a bottom surface of the base member 22 may be formed in region disposed below the lower end of the base member 22. The upper end of the insulation member 24 may be disposed at a height corresponding to the upper surface of the support plate 21. The upper end of the insulation member 24 may be disposed below a bottom surface of the focus ring 23. In addition, the insulation member 24 may be disposed on an outer circumference of the focus ring 23, and may be provided to surround at least a partial region of the focus ring 23. As an example, FIG. 1 shows the case that the upper end of the insulation member 24 is disposed below the focus ring 23 and the insulation member 24 is provided to surround a partial region of the support plate 21.

The outer ring 25 may be disposed in an outer circumference of the insulation member 24. The outer ring 25 may be provided in a ring structure having a predetermined height in the vertical direction. The outer ring 25 may be disposed to surround an upper portion of the insulation member 24. In addition, the outer ring 25 may be disposed to surround the focus ring 23. The outer ring 25 may be made of an insulation material.

The plasma excitation member 30 enables the energy for excitation of plasma to be applied to the process space PS. The plasma excitation member 30 may be located in the interior of the chamber 10. For example, the plasma excitation member 30 may be separately manufactured from the chamber 10 and connected to the chamber 10. Alternatively, the plasma excitation member 30 may be integrally provided with an upper structure of the chamber 10. For example, the upper structure of the chamber 10 may function as the plasma excitation member 30.

The plasma excitation member 30 may be located in an upper portion of the process space PS. The plasma excitation member 30 may be made of a conductive material and have a predetermined area. The plasma excitation member 30 may be located to face the support assembly 20 in the upward and downward direction.

The process gas introduced to the interior of the chamber 10 may be excited to plasma by the electric field formed in the interior of the chamber 10. Specifically, the process gas may be excited to plasma by a capacitively coupled plasma (CCP) source. The capacitively coupled plasma source may include an upper electrode and a lower electrode. The upper electrode and the lower electrode may be disposed in the interior of the chamber 10 along the upward and downward direction to face each other. By applying the high frequency power to at least one of the upper electrode and the lower electrode, an electromagnetic field is formed in a space between the upper electrode and the lower electrode, and the process gas supplied in this space may be excited to a plasma state. The upper electrode may be the plasma excitation member 30, and the lower electrode may a region provided in a metal material in the base member 22. The source power supply 40 for applying the high frequency power may be connected to only one of the upper electrode and the lower electrode. For example, the upper electrode may be grounded, and the source power supply 40 may be connected to only the lower electrode. In addition, the lower electrode may be grounded, and the source power supply 40 may be connected to only the upper electrode. In addition, the source power supply 40 may be connected both of the upper electrode and the lower electrode. As an example, FIG. 1 shows the case that the source power supply 40 is connected to the lower electrode.

A baffle 50 may be disposed in an outer circumference of the support assembly 20. The baffle 50 may be grounded. The baffle 50 may have a ring structure. A center of the baffle 50 may be located to correspond to a center of the support assembly 20. For example, a coupling ring 29 may be disposed in the outer circumference of the support assembly 20. The coupling ring 29 may be disposed on the outer circumference of the insulation member 24. In addition, the baffle 50 may be fixed in a structure disposed on the coupling ring 29. In addition, the outer ring 25 may be disposed on an inner end portion of the baffle 50.

The baffle 50 partitions a space located above the support assembly 20 and a space located in a lower portion of the chamber 10 from each other. The baffle 50 may adjust a flow amount of fluid discharged from the space located above the support assembly 20 to an exterior of the chamber 10. That is, reaction by-products generated in the substrate processing process may flow to the discharge hole 11 via the baffle 50. In addition, the baffle 50 may prevent plasma of the space located above the support assembly 20 from escaping to the outside. Accordingly, a space located below the baffle 50 may have a very low pressure compared to a space located above the baffle 50.

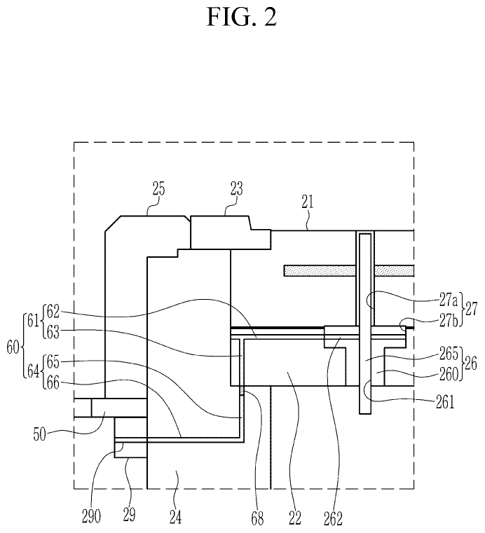

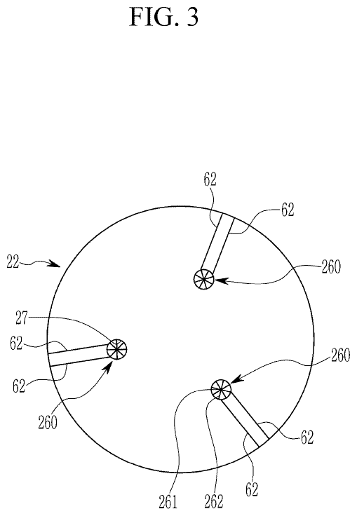

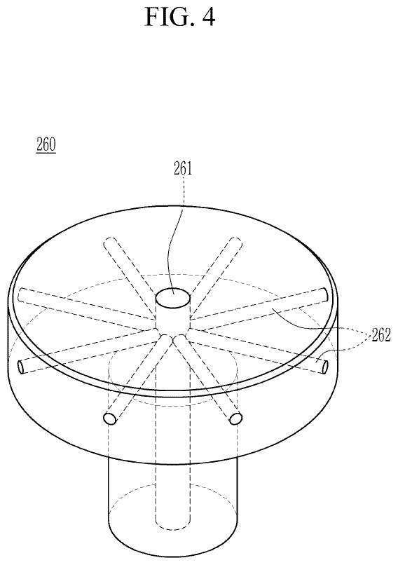

FIG. 2 is a drawing showing an example of a partial region of the support assembly 20 of FIG. 1. FIG. 3 is a horizontal cross-sectional view of an example of the base member 22. FIG. 4 is a drawing showing an example of a guide member 260 of FIG. 2.

Referring to FIG. 2 to FIG. 4, a pin receiving space 27 may be formed in the interior of the support assembly 20. The pin receiving space 27 may be formed across the support plate 21 and the base member 22. The pin receiving space 27 may be formed to penetrate the support plate 21 and be connected to the upper surface of the support plate 21. The pin receiving space 27 may be formed penetrate the base member 22 and to be connected to a lower surface of the base member 22. The pin receiving space 27 may have a cross-sectional area according to a direction perpendicular to the vertical direction that is different for each region.

The pin receiving space 27 may be provided in plurality. For example, the pin receiving space 27 may be located on a circumference about the center of the support assembly 20. As an example, FIG. 3 shows the case that the pin receiving space 27 is provided in a quantity of three.

The pin receiving space 27 may include an upper receiving space 27a and a lower receiving space 27b. The upper receiving space 27a may be located in an upper region of the pin receiving space 27. An upper end of the upper receiving space 27a may be connected to the upper surface of the support plate 21.

The lower receiving space 27b may be located in a lower region of the pin receiving space 27. At least a portion of the lower receiving space 27b may be located in an inner side of the base member 22. In addition, an upper portion of the lower receiving space 27b may be located on a lower inner side of the support plate 21. As an example, FIG. 2 shows the case that the lower receiving space 27b is located in the inner side of the base member 22.

A lower end of the lower receiving space 27b may be connected to the lower surface of the base member 22. The cross-sectional area according to the direction perpendicular to the vertical direction may be greater in the lower receiving space 27b than in the upper receiving space 27a.

A lift pin module 26 is disposed in an inner side of the pin receiving space 27. The lift pin module 26 may be provided in a plurality corresponding to the number of the pin receiving space 27. The lift pin module 26 may include the guide member 260 and a lift pin 265. The guide member 260 may be disposed in the lower receiving space 27b. A pin guide hole 261 may be penetratingly formed through the guide member 260 in the vertical direction. An internal connection hole 262 may be formed in the guide member 260. The internal connection hole 262 is formed between the pin guide hole 261 and an outer surface of the guide member 260. Accordingly, an inner end of the internal connection hole 262 may be connected to the pin guide hole 261, and an outer end of the internal connection hole 262 may be connected to the outer surface of the guide member 260. The internal connection hole 262 may be formed in a plurality along a circumference of the pin guide hole 261. A plurality of internal connection holes 262 may be located radially around the circumference of the pin guide hole 261.

The lift pin 265 may be disposed to be inserted into the pin guide hole 261. Accordingly, the vertical movement of the lift pin 265 is guided by the guide member 260. An upper portion of the lift pin 265 may be located in the upper receiving space 27a. A lower portion of the lift pin 265 may be located below the lower surface of the base member 22, and may be connected to a driving member for driving the lift pin 265. The lift pin 265 may be provided to be vertically movable, and the upper portion of the lift pin 265 may protrude above an upper surface of the support assembly 20 or may be accommodated in the interior of the support assembly 20.

A discharge passage 60 may be formed in the interior of the support assembly 20. The discharge passage 60 enables discharge with respect to a gap located in the interior of the support assembly 20. That is, the discharge passage 60 may formed to penetrate between the interior of the support assembly 20 and an outer surface of the support assembly 20. In addition, the discharge passage 60 is located to pass through the gap located in the interior of the support assembly 20, and the gap located in the interior of the support assembly 20 may be discharged through the discharge passage 60. Accordingly, the material escaped from the gap located in the interior of the support assembly 20 may flow to a space outside the outer surface of the support assembly 20.

An inner end of the discharge passage 60 may be connected to the pin receiving space 27. The inner end of the discharge passage 60 may be connected to the lower receiving space 27b. An outer end of the discharge passage 60 may be connected to the outer surface of the support assembly 20.

The discharge passage 60 may be provided in a plural quantity. The number of the discharge passage 60 may be larger than the number of the pin receiving space 27. In addition, at least one discharge passage 60 be may connected to the pin receiving space 27. As an example, FIG. 3 shows the case that two discharge passages 60 are connected to one pin receiving space 27.

The coupling ring 29 may be disposed in a region where the outer end of the discharge passage 60 is located on the outer surface of the support assembly 20. A connection hole 290 may be formed to pass through the coupling ring 29. An outer end of the connection hole 290 may be located on an outer surface of the coupling ring 29. An inner end of the connection hole 290 may be located on an inner surface of the coupling ring 29, and may be adjacent to the outer end of the discharge passage 60. Accordingly, the discharge passage 60 may be connected to the connection hole 290.

The discharge passage 60 may include a central passage part 61 and an edge passage part 64.

The central passage part 61 may be located in an interior of a central region of the support assembly 20. The central passage part 61 may be located in the interior of the base member 22. An inner end of the central passage part 61 may be connected to the pin receiving space 27. The inner end of the central passage part 61 may be connected to the lower receiving space 27b. An outer end of the central passage part 61 may be connected to on the outer surface of the base member 22 or bottom surface.

The central passage part 61 may include a central radial portion 62 and a central longitudinal portion 63. The central radial portion 62 may extend from the interior of the base member 22 in radial direction. An inner end of the central radial portion 62 may be connected to the pin receiving space 27. The inner end of the central radial portion 62 may be connected to the lower receiving space 27b. The central radial portion 62 may be penetratingly formed between the pin receiving space 27 and the outer surface of the base member 22, and an outer end of the central radial portion 62 may be connected to the outer surface of the base member 22.

The central longitudinal portion 63 may extend from the interior of the base member 22 in the upward and downward direction. An upper end of the central longitudinal portion 63 may be connected to the central radial portion 62. A lower end of the central longitudinal portion 63 may be connected to the lower surface of the base member 22.

The edge passage part 64 may be located in an edge region of the interior of the support assembly 20. The edge passage part 64 may be located in an interior of the insulation member 24. The edge passage part 64 may be penetratingly formed between an inner surface of the insulation member 24 and outer surface. Accordingly, an inner end of the edge passage part 64 may connected to the inner surface of the insulation member 24 facing the base member 22. In addition, an outer end of the edge passage part 64 may be connected to an outer surface of the insulation member 24. The outer end of the edge passage part 64 may be located below the baffle 50.

The edge passage part 64 may include an edge longitudinal portion 65 and an edge radial portion 66.

The edge longitudinal portion 65 may extend from the interior of the insulation member 24 in the upward and downward direction. An upper end of the edge longitudinal portion 65 may be connected to the inner surface of the insulation member 24. The upper end of the edge longitudinal portion 65 may be located adjacent to the lower end of the central longitudinal portion 63.

The edge radial portion 66 may be connected to the edge longitudinal portion 65. An inner end portion of the edge radial portion 66 may be connected to a lower portion of the edge longitudinal portion 65. The edge radial portion 66 may extend from the interior of the insulation member 24 in radial direction. An outer end of the edge radial portion 66 may be connected to the outer surface of the insulation member 24. The outer end of the edge radial portion 66 may be located below the baffle 50.

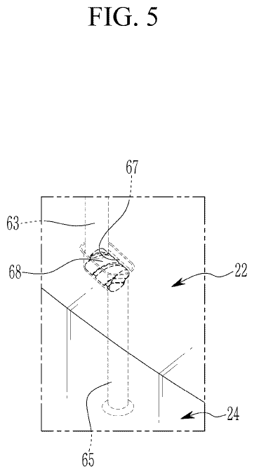

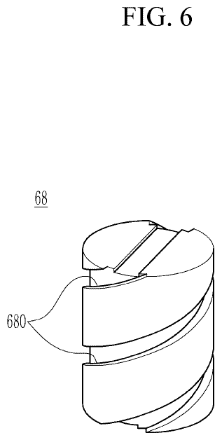

FIG. 5 is a drawing showing an example of a region where the base member 22 and the insulation member 24 are adjacent. FIG. 6 is a drawing showing an example of an arc prevention member 68 of FIG. 5.

Referring to FIG. 5 and FIG. 6, the arc prevention member 68 may be disposed in a partial section of the discharge passage 60. Specifically, an insertion region 67 may be formed in a partial section of the discharge passage 60. In addition, the arc prevention member 68 may be disposed in the insertion region 67. The insertion region 67 may be located in a region where components of the support assembly 20 face each other. The insertion region 67 may be located in a region where the base member 22 and the insulation member 24 face each other. The insertion region 67 may be formed on the inner surface of the insulation member 24 facing the base member 22, and may be located in an inner end portion of the edge passage part 64.

The arc prevention member 68 may be disposed in an inner side of the insertion region 67, and may increase a length of a partial section of the discharge passage 60 formed on the inner side of the insertion region 67. The arc prevention member 68 may be provided in a pillar structure having a predetermined length. A cross-section of the arc prevention member 68 perpendicular to a length direction may be circular, elliptical, polygonal, or the like. A passage enlarging portion 680 for increasing the length of a partial section of the discharge passage 60 may be formed on an outer surface of the arc prevention member 68. The passage enlarging portion 680 may be formed in a groove structure on the outer surface of the arc prevention member 68. The passage enlarging portion 680 may be formed such that regions formed at both ends of the arc prevention member 68 are connected to each other. For example, the passage enlarging portion 680 may be formed in a spiral structure on the outer surface of the arc prevention member 68. In addition, the passage enlarging portion 680 may be formed on an upper surface or a lower surface of the both ends of the arc prevention member 68 in the length direction to cross the central region. In the outer surface of the arc prevention member 68, an inner surface of the insertion region 67 may have a shape corresponding to a region excluding the region where the passage enlarging portion 680 is formed.

When the arc prevention member 68 is disposed in the insertion region 67, a region where the inner surface of the insertion region 67 and the arc prevention member 68 are spaced apart may form a partial section of the discharge passage 60. In addition, by the passage enlarging portion 680, passage may be more effectively formed between the inner surface of the insertion region 67 and the passage enlarging portion 680. A partial section of the discharge passage 60 formed between the inner surface of the insertion region 67 and the arc prevention member 68 may have a smaller area along a direction crossing the length direction of the discharge passage 60 than an adjacent region of the discharge passage 60. In addition, when the passage enlarging portion 680 is formed in a spiral structure on the outer surface of the arc prevention member 68, a length of a partial section of the discharge passage 60 formed by the passage enlarging portion 680 may be longer than a length of the arc prevention member 68.

The insertion region 67 may have a greater area along a direction crossing the length direction of the discharge passage 60 than an adjacent region of the discharge passage 60. In addition, the arc prevention member 68 may be disposed in the insertion region 67, in the form that the length direction is inclined with respect to an adjacent region of the length direction of the discharge passage 60. Accordingly, an entire length of the discharge passage 60 may be further increased, and the arc prevention member 68 may be stably fixed to the insertion region 67.

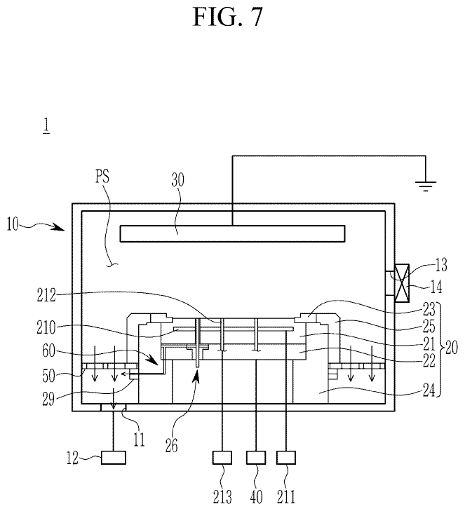

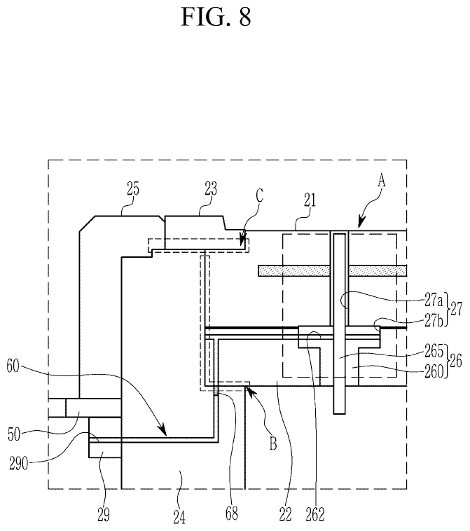

FIG. 7 is a drawing for explaining an example of a state in which discharge is made into the interior of the support assembly 20 through the discharge passage 60 when the substrate processing apparatus 1 operates. FIG. 8 is a drawing for explaining an example of a region where discharge is made into a space formed in the interior of the support assembly 20 through the discharge passage 60.

Referring to FIG. 7 and FIG. 8, the discharge may be performed by the discharge passage 60 with respect to a region in the interior of the support assembly 20 where the arc may occur, and thus arcing may be prevented or reduced.

In the substrate processing process using plasma, an arc may occur in a space formed in the interior of the support assembly 20. Additionally, as the waveform of the voltage used in the substrate processing process is diversified, the voltage difference between regions within the support assembly 20 increases, which may intensify arc occurrence. In addition, as the thermal expansion coefficients of the components of the support assembly 20 are different, the size of the gap between the components of the support assembly 20 may change during substrate processing. In particular, when a low-temperature plasma process is introduced, the size of the gap between the components of the support assembly 20 may become larger during the substrate processing process. As a solution to this, arc generation can be prevented or reduced by performing discharging on the space formed inside the support assembly 20. This may be due to the fact that the gap formed inside the support assembly 20 is depressurized as discharge is performed on the gap formed inside the support assembly 20.

When discharge with respect to the interior of the chamber 10 is performed according to an operation of the discharge member 12, discharge is also performed in the discharge passage 60, in a direction from an inner end to an outer end. Accordingly, discharge may occur with respect to the pin receiving space 27 (hereinafter, called first region) A through the discharge passage 60. In addition, as the internal connection hole 262 is formed in the guide member 260, the discharge may be more effectively performed with respect to an interval formed between the lift pin modules 26.

In addition, discharge may occur with respect to a space (hereinafter, called a second region) B formed between the base member 22 and the insulation member 24 through the discharge passage 60. In addition, the central radial portion 62 of the central passage part 61 may be connected to the outer surface of the base member 22, and the discharge may be effectively performed on a space formed between the insulation member 24 and the outer surface of the base member 22.

In addition, the discharge may be performed with respect to a space (hereinafter, called a third region) C formed between the insulation member 24 and the focus ring 23, between the focus ring 23 and the support plate 21, and between the insulation member 24 and the support plate 21. That is, the third region C may be connected to a second region B, and the discharge may be performed on the third region C via the second region B. In addition, the central radial portion 62 of the central passage part 61 may be connected to the outer surface of the base member 22, and the discharge may be more effectively performed with respect to the third region C. In addition, when the outer side surface of the base member 22 is aligned with the lower portion of the outer side surface of the support plate 21 in the upward and downward direction, the discharge may be more effectively performed on the third region C via the second region B.

In addition, the discharge passage 60 may include a section extending in a radial direction and a section extending in the upward and downward direction. Compared to the limited volume that the support assembly 20 has, the entire length of the discharge passage 60 may be increased. As the length of the discharge passage 60 increases, arc generation may be prevented more effectively.

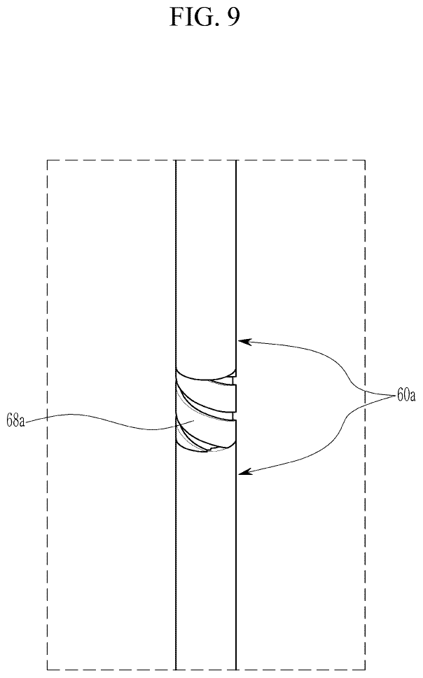

FIG. 9 a drawing showing an example of an arrangement state of an arc prevention member 68a.

Referring to FIG. 9, the arc prevention member 68a may be disposed such that the length direction of the arc prevention member 68a face the length direction of an adjacent region of a discharge passage 60a. For example, the length directional axis of the arc prevention member 68a may coincide with the length directional central axis of an adjacent region of the discharge passage 60a.

In addition, the structure of the arc prevention member 68a, the region where the arc prevention member 68a is disposed in the interior of the support assembly 20, and the discharge passage 60a is the same as or similar to the structure described with reference to FIG. 5 and FIG. 6, and the redundant description is not repeatedly included herein.

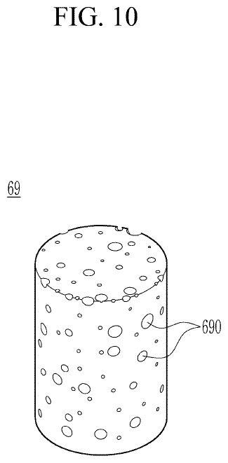

FIG. 10 is a drawing showing an example of an arc prevention member 69.

Referring to FIG. 10, the arc prevention member 69 may be provided in a pillar structure having a predetermined length. A cross-section of the arc prevention member 69 perpendicular to the length direction may be circular, elliptical, polygonal, or the like. Passage enlarging portions 690 for increasing the length of a partial section of the discharge passages 60 and 60a may be formed on the arc prevention member 69. The passage enlarging portion 690 may be an air gap formed in the arc prevention member 69. The passage enlarging portions 690 may be formed on an outer surface of the arc prevention member 69 or an interior of the arc prevention member 69 to be connected to each other, to form passages.

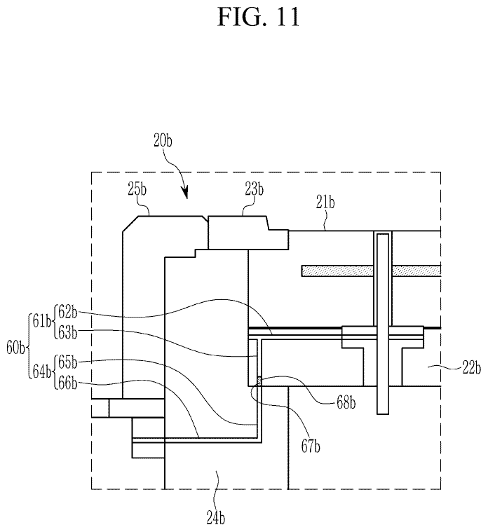

FIG. 11 is a drawing showing an example of a partial region of a support assembly 20b.

Referring to FIG. 11, the support assembly 20b may include a support plate 21b, a base member 22b, a focus ring 23b, an insulation member 24b and an outer ring 25b.

A discharge passage 60b may be formed in an interior of the support assembly 20b. The discharge passage 60b may include a central passage part 61b and an edge passage part 64b. The central passage part 61b may include a central radial portion 62b and a central longitudinal portion 63b. The edge passage part 64b may include an edge longitudinal portion 65b and an edge radial portion 66b.

An arc prevention member 68b may be disposed in a partial section of the discharge passage 60b. The arc prevention member 68b may be disposed in an insertion region 67b. The insertion region 67b may be formed on an outer surface of the base member 22b facing the insulation member 24b, and may be located in an outer end portion of the central passage part 61b. The insertion region 67b may be located in a lower end portion of the central longitudinal portion 63b.

In addition, structure of the support assembly 20b, structure of the discharge passage 60b, structure of the arc prevention member 68b, the arrangement form of the arc prevention member 68b are identical or similar to as described above with reference to FIG. 1 to FIG. 6, FIG. 9, FIG. 10, and accordingly, repeated description is not included herein.

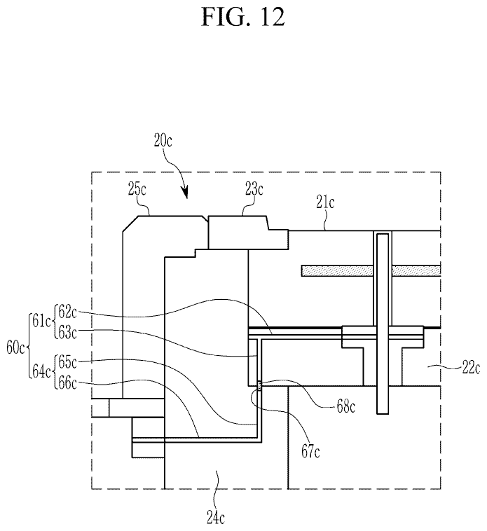

FIG. 12 is a drawing showing an example of a partial region of a support assembly 20c.

Referring to FIG. 12, the support assembly 20c may include a support plate 21c, a base member 22c, a focus ring 23c, an insulation member 24c and an outer ring 25c.

A discharge passage 60c may be formed in an interior of the support assembly 20c. The discharge passage 60c may include a central passage part 61c and an edge passage part 64c. The central passage part 61c may include a central radial portion 62c and a central longitudinal portion 63c. The edge passage part 64c may include an edge longitudinal portion 65c and an edge radial portion 66c.

An arc prevention member 68c may be disposed in a partial section of the discharge passage 60c. The arc prevention member 68c may be disposed in an insertion region 67c.

The insertion region 67c may be formed on an inner surface of the insulation member 24c facing the base member 22c and an outer surface of the base member 22c facing the insulation member 24c, and may be located across an outer end portion of the central passage part 61c and an inner end portion of the edge passage part 64c. The insertion region 67c may be located across a lower end portion of the central longitudinal portion 63c and an upper end portion of the edge longitudinal portion 65c.

In addition, structure of the support assembly 20c, structure of the discharge passage 60c, structure of the arc prevention member 68c, the arrangement form of the arc prevention member 68c are identical or similar to as described above with reference to FIG. 1 to FIG. 6, FIG. 9, FIG. 10, and accordingly, repeated description is not included herein.

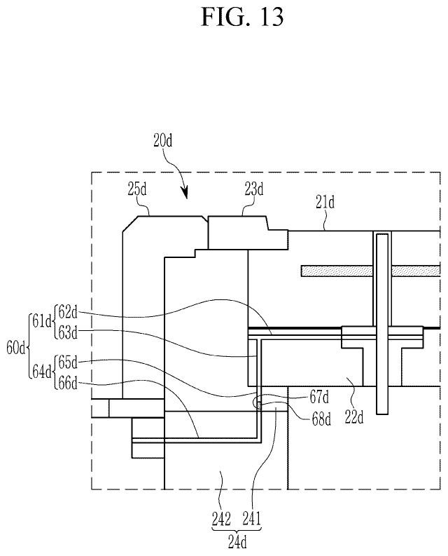

FIG. 13 is a drawing showing an example of a partial region of a support assembly 20d.

Referring to FIG. 13, the support assembly 20d may include a support plate 21d, a base member 22d, focus ring (23d, an insulation member 24d and an outer ring 25d.

The insulation member 24d may include an upper insulation member 241 and a lower insulation member 242.

The upper insulation member 241 may be disposed in an upper region of the insulation member 24d. The upper insulation member 241 may be disposed on an outer circumference of the base member 22d. To this end, at least a partial region of the upper insulation member 241 may be provided in a ring structure having a predetermined height, in the upward and downward direction. In addition, the upper insulation member 241 may support the base member 22d. To this end, in the upper insulation member 241, a step supporting a bottom surface of the base member 22d may be formed in region located below a lower end of the base member 22d.

The lower insulation member 242 may be disposed in a lower region of the insulation member 24d. The upper insulation member 241 may be disposed on the lower insulation member 242.

A discharge passage 60d may be formed in an interior of the support assembly 20d. The discharge passage 60d may include a central passage part 61d and an edge passage part 64d. The central passage part 61d may include a central radial portion 62d and a central longitudinal portion 63d. The edge passage part 64d may include an edge longitudinal portion 65d and an edge radial portion 66d.

The edge longitudinal portion 65d may be located across the upper insulation member 241 and the lower insulation member 242. The edge radial portion 66d may be located in the lower insulation member 242.

An arc prevention member 68d may be disposed in a partial section of the discharge passage 60d. The arc prevention member 68d may be disposed in a section between both ends of the edge passage part 64d.

The arc prevention member 68d may be disposed in an insertion region 67d. The insertion region 67d may be located in an interior of the insulation member 24d. The insertion region 67d may be located in a region where the upper insulation member 241 and the lower insulation member 242 face each other. The insertion region 67d may be formed on a bottom surface of the upper insulation member 241 facing the lower insulation member 242, and the insertion region 67d may be located in a section between both ends of the edge longitudinal portion 65d.

In addition, structure of the support assembly 20d, structure of the discharge passage 60d, structure of the arc prevention member 68d, the arrangement form of the arc prevention member 68d are identical or similar to as described above with reference to FIG. 1 to FIG. 6, FIG. 9, FIG. 10, and accordingly, repeated description is not included herein.

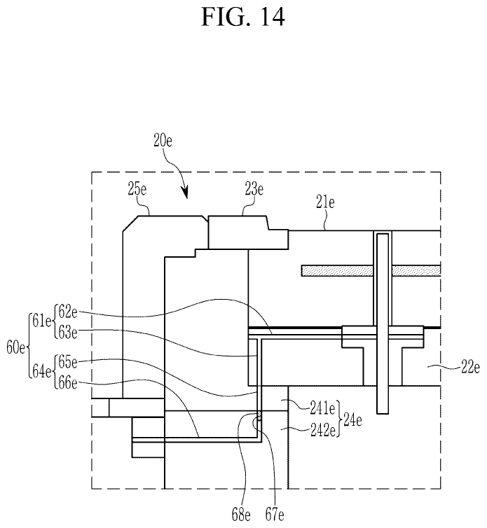

FIG. 14 is a drawing showing an example of a partial region of a support assembly 20e.

Referring to FIG. 14, the support assembly 20e may include a support plate 21e, a base member 22e, a focus ring 23e, an insulation member 24e and an outer ring 25e.

The insulation member 24e may include an upper insulation member 241e and a lower insulation member 242e.

A discharge passage 60e may be formed in an interior of the support assembly 20e. The discharge passage 60e may include a central passage part 61e and an edge passage part 64e. The central passage part 61e may include a central radial portion 62e and a central longitudinal portion 63e. The edge passage part 64e may include an edge longitudinal portion 65e and an edge radial portion 66e.

The edge longitudinal portion 65e may be located across the upper insulation member 241e and the lower insulation member 242e. The edge radial portion 66e may be located in the lower insulation member 242e.

An arc prevention member 68e may be disposed in a partial section of the discharge passage 60e. The arc prevention member 68e may be disposed in a section between both ends of the edge passage part 64e. The arc prevention member 68e may be disposed in a section between both ends of the edge longitudinal portion 65e. The arc prevention member 68e may be disposed in an insertion region 67e. The insertion region 67e may be located in an interior of the insulation member 24e. The insertion region 67e may be formed on an upper surface of a lower insulation member 24e facing an upper insulation member 24e, and the insertion region 67 may be located in the section between both ends of the edge longitudinal portion 65e.

In addition, structure of the support assembly 20e, structure of the discharge passage 60e, structure of the arc prevention member 68e, the arrangement form of the arc prevention member 68e are identical or similar to as described above with reference to FIG. 1 to FIG. 6, FIG. 9, FIG. 10, and accordingly, repeated description is not included herein.

In addition, the insulation member 24e is identical or similar to the insulation member 24d described above with reference to FIG. 13, and accordingly, the repeated description is not included herein.

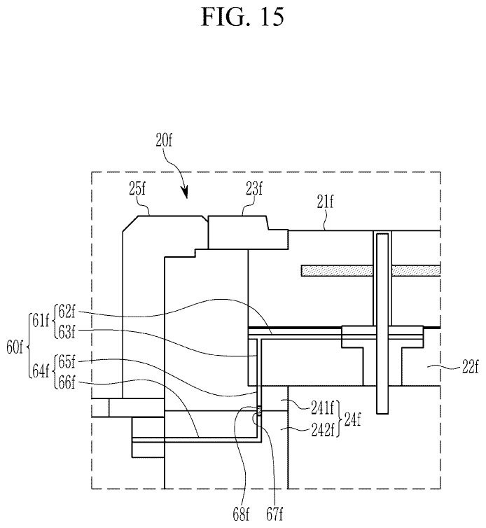

FIG. 15 is a drawing showing an example of a partial region of a support assembly 20f.

Referring to FIG. 15, the support assembly 20f may include a support plate 21f, a base member 22f, a focus ring 23f, an insulation member 24f and an outer ring 25f.

The insulation member 24f may include an upper insulation member 241f and a lower insulation member 242f.

A discharge passage 60f may be formed in an interior of the support assembly 20f. The discharge passage 60f may include a central passage part 61f and an edge passage part 64f. The central passage part 61f may include a central radial portion 62f and a central longitudinal portion 63f. The edge passage part 64f may include an edge longitudinal portion 65f and an edge radial portion 66f.

The edge longitudinal portion 65f may be located across an upper insulation member 24f and a lower insulation member 24f. The edge radial portion 66f may be located in the lower insulation member 24f.

An arc prevention member 68f may be disposed in a partial section of the discharge passage 60f. The arc prevention member 68f may be disposed in a section between both ends of the edge passage part 64f. The arc prevention member 68f may be disposed in a section between both ends of the edge longitudinal portion 65f.

The arc prevention member 68f may be disposed in an insertion region 67f. The insertion region 67f may be located in an interior of the insulation member 24f. The insertion region 67f may be formed on a lower surface of the upper insulation member 241f facing the lower insulation member 24f and an upper surface of the lower insulation member 242f facing the upper insulation member 241f, and may be located across the upper insulation member 241f and the lower insulation member 242f. Accordingly, the arc prevention member 68f may be disposed across the upper insulation member 241f and the lower insulation member 242f.

In addition, structure of the support assembly 20f, structure of the discharge passage 60f, structure of the arc prevention member 68f, the arrangement form of the arc prevention member 68f are identical or similar to as described above with reference to FIG. 1 to FIG. 6, FIG. 9, FIG. 10, and accordingly, repeated description is not included herein.

In addition, the insulation member 24f is identical or similar to the insulation member 24d of FIG. 13, and the repeated description is not included herein.

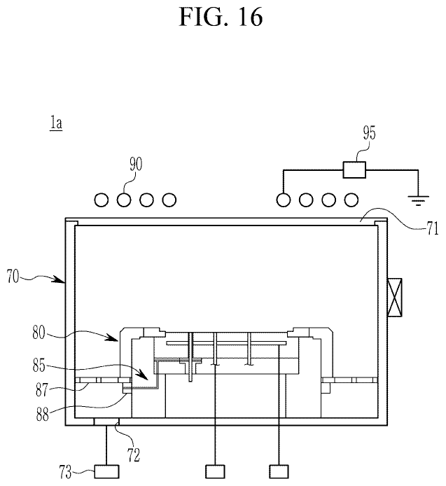

FIG. 16 is a drawing showing an example of a substrate processing apparatus 1a.

Referring to FIG. 16, the substrate processing apparatus 1aa may include a chamber 70, a support assembly 80 and a plasma excitation member 90.

The substrate processing apparatus 1a processes the substrate by using plasma. For example, the substrate processing apparatus 1a may perform etching process or the like by using excited plasma.

At least a portion of an upper part of the chamber 70 may be formed of a dielectric substance. An upper wall 71 of at least a partial region of the chamber 70 may be made of a dielectric substance. A discharge hole 72 may be formed on a first side of the chamber 70. A discharge member 73 be may connected to the discharge hole 72. A remaining structure of the chamber 70 is identical or similar to the substrate processing apparatus 1 of FIG. 1, and accordingly, the repeated description is not included herein.

The support assembly 80 may be disposed in an interior of the chamber 70. The support assembly 80 supports the substrate. A discharge passage 85 may be formed in an interior of the support assembly 80. The support assembly 80 and the discharge passage 85 is identical or similar to as described above with reference to FIG. 1 to FIG. 15, and accordingly, the repeated description is not included herein.

A baffle 87 may be disposed in an outer circumference of the support assembly 80. A coupling ring 88 is disposed in the outer circumference of the support assembly 80, and the baffle 87 may be disposed on the coupling ring 88. The baffle 87 and the coupling ring 88 is identical or similar to the baffle 50 and the coupling ring 29 described above with reference to FIG. 1, and accordingly, the repeated description is not included herein.

The plasma excitation member 90 enables the energy for excitation of plasma to be applied to the interior of the chamber 70. The plasma excitation member 90 may have an antenna structure. The plasma excitation member 90 may be disposed in an exterior of the chamber 70. The plasma excitation member 90 may be disposed adjacent to an upper surface of the upper wall 71 of the chamber 70. The plasma excitation member 90 may be disposed to face an interior space of the chamber 70 interposing the upper wall 71 of the chamber 70.

The plasma excitation member 90 may be electrically connected to a source power supply 95. The source power supply 95 may be provided as the high frequency power supply configured to generate the high frequency power. The source power supply 95 may be provided as an RF power supply. The plasma excitation member 90 generates electromagnetic wave through the electric power provided by the source power supply 95. The gas supplied to the interior of the chamber 70 may be excited to plasma by the electromagnetic waves generated in the plasma excitation member 90.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the implementations of the present disclosure have been described, it is to be understood that the disclosure is not limited to the disclosed implementations, but, on the contrary, is intended to cover various modifications and equivalent arrangements included within the spirit and scope of the appended claims.

What is claimed is:

1. A substrate processing apparatus, comprising:
a chamber; and
a support assembly disposed in the chamber,
wherein the support assembly comprises:
a base member;
a support plate disposed on the base member;
an insulation member disposed on at least a partial region of an outer circumference of the base member; and
a discharge passage located in the insulation member, the discharge passage having an outer end connected to an outer surface of the insulation member.

2. The substrate processing apparatus of claim 1, wherein the discharge passage comprises:
a central passage part located in the base member; and
an edge passage part located in the insulation member.

3. The substrate processing apparatus of claim 2, wherein:
a pin receiving space is located in the base member; and
the central passage part is connected to the pin receiving space.

4. The substrate processing apparatus of claim 3, wherein the support assembly further comprising:
a guide member disposed in the pin receiving space,
wherein a pin guide hole passes through the guide member in a vertical direction, and an internal connection hole is located between the pin guide hole and an outer surface of the guide member, the internal connection hole passing through the guide member.

5. The substrate processing apparatus of claim 4, wherein a plurality of internal connection holes are located along a circumference of the pin guide hole.

6. The substrate processing apparatus of claim 2, wherein the central passage part comprises:
a central radial portion in the base member and extending in a radial direction; and
a central longitudinal portion in the base member and connected to the central radial portion, the central longitudinal portion extending in a vertical direction.

7. The substrate processing apparatus of claim 6, wherein an outer end of the central radial portion is connected to an outer surface of the base member.

8. The substrate processing apparatus of claim 2, wherein the edge passage part comprises:
an edge longitudinal portion in the insulation member and extending in a vertical direction; and
an edge radial portion in the insulation member and connected to the edge longitudinal portion, the edge radial portion extending in a radial direction.

9. The substrate processing apparatus of claim 2, wherein the support assembly further comprising an arc prevention member disposed in a partial section of the discharge passage.

10. The substrate processing apparatus of claim 9, wherein the arc prevention member has a pillar structure with a predetermined length, and passage enlarging portion of a groove structure is located on an outer surface of the arc prevention member.

11. The substrate processing apparatus of claim 9, wherein the arc prevention member has a pillar structure with a predetermined length, and the arc prevention member has a pore.

12. The substrate processing apparatus of claim 9, wherein the arc prevention member is disposed in a region where the base member and the insulation member face each other.

13. The substrate processing apparatus of claim 9, wherein the arc prevention member is disposed in the insulation member.

14. The substrate processing apparatus of claim 13, wherein the insulation member comprises:
a lower insulation member; and
an upper insulation member disposed on the lower insulation member,
wherein the arc prevention member is disposed in a region where the upper insulation member and the lower insulation member face each other.

15. A substrate processing apparatus, comprising:
a chamber; and
a support assembly disposed in the chamber,
wherein the support assembly comprises a plurality of components, a gap is formed between the plurality of components in the support assembly, and a discharge passage passes through the gap, and
wherein an outer end of the discharge passage is connected to an outer surface of the support assembly.

16. The substrate processing apparatus of claim 15, wherein:
a pin receiving space is located in the support assembly; and
an inner end of the discharge passage is connected to the pin receiving space.

17. The substrate processing apparatus of claim 15, comprising:
a baffle disposed on an outer circumference of the support assembly, and
the outer end of the discharge passage is below the baffle.

18. The substrate processing apparatus of claim 15, wherein the support assembly comprises:
an arc prevention member disposed in a partial section of the discharge passage.

19. A substrate processing apparatus, comprising:
a chamber having a lower region where a discharge hole is located;
a support assembly disposed in the chamber; and
a baffle disposed on an outer circumference of the support assembly,
wherein the support assembly comprises:
a base member;
a support plate disposed on the base member;
an insulation member disposed on at least a partial region of an outer circumference of the base member; and
a discharge passage located in the insulation member,
wherein an outer end of the discharge passage is connected to an outer surface of the insulation member, and the outer end of the discharge passage is below the baffle.

20. The substrate processing apparatus of claim 19, wherein:
a pin receiving space is located in the base member; and
a central passage part is connected to the pin receiving space.
